(19) United States
(12) Patent Application Publication
(10) Pub. No.: US 2011/0121821 A1
(43) Pub. Date: May 26, 2011

(54) MAGNETIC CORE FOR ELECTRIC CURRENT SENSORS

(75) Inventors: Yong Sul Song, Seoul (KR); Jin Taek Nam, Gimpo-si (KR); Dong Wook Jang, Gimpo-si (KR)

(73) Assignee: AMOGREENTECH CO., LTD., Kimpo-si (KR)

(21) Appl. No.: 12/995,520

(22) PCT Filed: Nov. 5, 2008
(86) PCT No.: PCT/KR2008/006510

§ 371 Date: Dec. 1, 2010

(30) Foreign Application Priority Data
Jun. 3, 2008 (KR) 10-2008-0051988

(51) Int. Cl. G01R 5/06

(52) U.S. Cl. 324/151 A

(57) ABSTRACT

Provided is a magnetic core having an appropriate range of permeability and a high magnetic flux density, thereby being configured to have a small phase difference and a small size. The magnetic core can be use for electric current sensors. The magnetic core is made of an amorphous alloy having a composition represented by the general formula: FeₐM_{b}Si_{c}B_{d}M′ₑ, in which M is at least one element that is selected from Ni and Co, and M′ is Cr, and a to e are atomic % and numbers satisfying 30≦a≦80, 1≦b≦50, 0.1≦c≦20, 0.1≦d≦20, and 0≦e≦10, respectively, and wherein the amorphous alloy has a magnetic flux density of 1.2 T to 1.7 T, and a permeability of 1,000 to 4,000.

### TECHNICAL FIELD

This invention relates to a magnetic core for electric current sensors, and more particularly, to a magnetic core for electric current sensors, in which the magnetic core has an appropriate range of permeability and a high magnetic flux density, thereby being configured to have a small phase difference and a small size.

### BACKGROUND ART

Electric current sensors are devices for detecting electric current by converting high electric current into low electric current in order to control or monitor high electric current. In this case, an electric current ratio of an electric current sensor is inversely proportional to the number of primary and secondary winding coils. For example, in the case that the turn number of a primary winding coil of an electric current sensor is one and the turn number of a secondary winding coil of the electric current sensor is 2,500, an electric current of 40 mA can be obtained at the secondary side of the electric current sensor, with respect to an electric current of 100 A at the primary side of the electric current sensor.

Recently, a main electric power source having a frequency of 50 Hz or 60 Hz that is supplied in individual homes or industrial fields, includes DC components and AC components. The reason why the main electric power source including DC components and AC components is applied to the electric current sensor is to solve a problem that an accuracy falls because it is difficult to accurately measure distorted waveform of half-wave signal detected from the AC components, at the time of measurement of electric current. Accordingly, the main electric power source which is applied to the electric current sensor includes DC components in addition to AC components.

However, the electric current sensor into which AC components appearing as a sinusoidal wave are applied may be more quickly saturated even in a small amount of DC components. As a result, it is difficult for the electric current sensor to properly measure electric current. Thus, an electric current sensor for use in power meters of IEC standard having an accuracy of a given extent or less (for example, 3% or less) has been required even if DC components are included in AC components.

It has been well-known that a point in time when a magnetic flux density which is induced according to intensity of a magnetic field that is applied to a magnetic core is saturated is changed depending on the material of the magnetic core. In other words, a saturation characteristic for DC and AC electric current components appear differently according to the material of the magnetic core.

In general, if a magnetic flux density is large, intensity of an applied magnetic field which is saturated is large. Accordingly, magnitudes of DC and AC electric current components flowing in a primary electric current become large. A slope on a curve of a magnetic flux density to an applied magnetic field intensity (called a B-H loop), is called a permeability. In contrary, if a permeability is small, an applied magnetic field intensity required for saturation of a magnetic flux density increases.

However, if a permeability decreases, an applied magnetic field intensity increases. In this case, a phase difference between primary and secondary electric currents which are important in a watt-hour meter becomes large. Accordingly, burden of an electronic circuit and a software process increases in order to compensate for the phase difference.

On the other hand, if a phase difference is decreased by increasing a permeability, magnitude of DC components of an electric current decreases by an increase in a permeability rate. There is a method of increasing a magnetic flux path of a magnetic core as another method of increasing a permeability and a use area with respect to DC electric current components.

A volume of a magnetic core can be expressed as a product of an average magnetic flux path of a magnetic core and a sectional area of the magnetic core. Here, it can be seen that if an average magnetic flux path of a magnetic core increases, volume of the magnetic core increases and weight of the magnetic core also increases.

To sum up, magnitude of a magnetic flux density should be large as much as possible, in order to lessen a phase difference of an electric current sensor and simultaneously increase a use area with respect to DC electric current components. In addition, in order to prevent magnitude of the magnetic core from being increased unnecessarily, it can be seen that a permeability should have a value within a predetermined range.

According to such a need, there has been proposed a technology of manufacturing an electric current sensor by using a magnetic core made of Fe-based nanocrystalline alloys and Co-based amorphous alloys, in order to solve a problem of a saturation phenomenon that happens in the case that DC components have been included in AC components.

For example, a magnetic core for electric current sensors is disclosed in European Patent Laid-open Publication No. 1 840 906, in which the magnetic core is manufactured by using Fe-based nanocrystalline alloys and a permeability of the magnetic core is about 2,500 to 3,000, and a magnetic flux density thereof is 1.2 T or higher. However, the electric current sensor includes copper (Cu) as an essential component in order to obtain microstructures having nanocrystalline particles. Therefore, although an amount of copper is limited, fragility of a magnetic core material increases, that is, the magnetic core is brittle. As a result, it is difficult to perfectly remove a problem on treatment of the magnetic core. Further, it is difficult to control a process variable at the time of crystallization heat treatment for obtaining nanocrystalline particles. Still further, there is a problem that intensity of a magnetic field which is applied at the time of heat treatment of the magnetic field is set excessively high.

In addition, a magnetic core for electric current sensors is disclosed in U.S. Pat. No. 6,563,411, in which the magnetic core is manufactured by using Co-based nanocrystalline alloys and a permeability of the magnetic core is about 1,000 to 1,900, and a magnetic flux density thereof is approximately 0.85 T to 1.0 T. However, there are problems that the Co-based magnetic core is made of cobalt (Co) which is expensive as a main raw material and an obtained magnetic flux density is too low.

### DISCLOSURE

### Technical Problem

To solve the above problems, it is an object of the present invention to provide a magnetic core for electric current sensors in which the magnetic core cannot only increase a use area with respect to DC components although inexpensive Fe-based amorphous alloys are used as a material of the magnetic core, but also a phase difference is small and a magnetic flux density is very large.

### Technical Solution

To accomplish the above object of the present invention, according to an aspect of the present invention, there is provided a magnetic core for electric current sensors, the magnetic core made of an amorphous alloy having a composition represented by the general formula: FeₐM_{b}Si_{c}B_{d}M′ₑ, wherein M is at least one element that is selected from Ni and Co, and M′ is Cr, and a to e are atomic % and numbers satisfying 30≦a≦80, 1≦b≦50, 0.1≦c≦20, 0.1≦d≦20, and 0≦e≦10, respectively, and wherein the amorphous alloy has a magnetic flux density of 1.2 T to 1.7 T, and a permeability of 1,000 to 4,000.

Preferably but not necessarily, the element M is limited to only Ni instead of Co considering a manufacturing cost of the magnetic core, in which case a to e are atomic % and numbers satisfying 50≦a≦80, 3≦b≦30, 6≦c≦10, 10≦d≦20, and 0≦e≦5, respectively, thereby obtaining the magnetic core for electric current sensors having desired magnetic characteristics.

Preferably but not necessarily, in the case that the element M is limited to only Co instead of Ni, the magnetic core for electric current sensors having a high saturation magnetic flux density due to excellent magnetic properties of Co. As well, there is an advantage that Cr may not be added separately due to an excellent corrosion-resistance property of Co.

Preferably but not necessarily, in the case of a heat treatment condition embodying the magnetic core for electric current sensors according to the present invention, a heat treatment temperature is 200 to 600° C., and a heat treatment time is 20 to 1,000 minutes, and intensity of an applied magnetic field is 100 to 6,000 Gauss.

Preferably but not necessarily, the magnetic core for electric current sensors according to the present invention is an alloy composite comprising Fe, Si, and B, and a phase difference between primary and secondary electric currents of the magnetic core for electric current sensors has a value of 10° or below.

Preferably but not necessarily, in this invention, the magnetic core for electric current sensors comprises Fe as a main component, to which Si and B that are well-known as amorphous formation elements are added, to accordingly employing a three-element alloy of Fe—Si—B which is suitable for manufacturing a Fe-based amorphous ribbon.

Preferably but not necessarily, the element M is selected from Co and Ni that are ferromagnetic elements to improve magnetic characteristics of the magnetic core, to thereby control a permeability of the Fe-based amorphous magnetic core within an optimal range, and simultaneously increase a saturation magnetic flux density. Meanwhile, preferably but not necessarily, in this invention, an element Cr playing an important role of enhancing a corrosion-resistance property of the amorphous alloy is added as the element M′.

If the components and compositions of the respective elements selected in the alloy for the magnetic core are beyond the predetermined ranges, the desired magnetic characteristics or mechanical characteristics as well as the permeability and the magnetic flux density cannot be satisfied.

The magnetic core of this invention has a permeability of a value of 1,000 to 4,000, preferably 1,400 to 3,000. Here, if the permeability is too small, the phase difference between the primary and secondary electric currents is undesirably excessively large. On the contrary, if the permeability is too large, the magnetic flux density for DC components of the electric current is early saturated. Accordingly, since the size of the magnetic core should be enlarged in order to sufficiently secure a use area as an electric current sensor, it is undesirable to make the magnetic core have the too large permeability.

To reduce size of the electric current sensor, it is desirable to use a magnetic core having a large magnetic flux density. In this invention, the magnetic flux density of the magnetic core for the electric current sensors has a very high value of 1.7 T or so at maximum.

### Advantageous Effects

As described above, a magnetic core for electric current sensors that is fabricated of Fe-based amorphous alloys according to this invention, has an advantage in a manufacturing process which does not need a crystallization heat treatment process that is a post-process, unlike a magnetic core that is made of Fe-based nanocrystalline alloys. In addition, the magnetic core for electric current sensors that is fabricated of Fe-based amorphous alloys according to this invention, has an appropriate range of permeability and a high magnetic flux density. Accordingly, although DC components are included in the primary electric current that is applied to a primary winding coil, an abrupt saturation phenomenon of the magnetic flux density in the use area of the DC components is prevented, to thus make it possible to increase the use area.

In addition, since the magnetic core for electric current sensors that is fabricated of Fe-based amorphous alloys according to this invention, has an appropriate range of permeability and a high magnetic flux density, the phase difference between the primary and secondary electric currents can be reduced, to thereby make size of the magnetic core small. As a result, there is an advantage that the magnetic core according to the present invention can be industrially utilized.

### DESCRIPTION OF DRAWINGS

The above and other objects and advantages of the present invention will become more apparent by describing the preferred embodiments thereof in detail with reference to the accompanying drawings in which:

FIG. 1 is a graphical view illustrating a heat treatment temperature profile when a magnetic core according to an embodiment of the present invention is fabricated;

FIG. 2 is a graphical view illustrating results which are obtained by comparing a direct-current superposition characteristic between a magnetic core according to the present invention and a conventional magnetic core; and

FIG. 3 is a graphical view illustrating a phase difference of a magnetic core according to an embodiment of the present invention.

### BEST MODE

Hereinbelow, a magnetic core for electric current sensors according to the present invention will be described with reference to the accompanying drawings.

An amorphous alloy of a composition of Fe_{60.6}Co₂₀B_{14.4}Si₅ is fabricated into an amorphous ribbon of thickness of 20 μm and width of 6.5 mm, by a rapid solidification process, and is wound up into a toroidal type core of an outer diameter of 31 mm×an inner diameter of 26 mm×a height of 6.5 mm in size, and then magnetic characteristics have been measured according to a heat treatment temperature and time. The results have been illustrated in the following Tables 1 and 2.

TABLE 1
Magnetic characteristics of a magnetic core according to a heat treatment
temperature (a measurement condition: 60 Hz, Hₘ ≈ 1,000 A/m)

| | | Magnetic | | | Saturation | |
|---|---|---|---|---|---|---|
| Temperature | Time | field | Permeability | Coercivity | magnetic flux | Squareness |
| [° C.] | [min] | [Gauss] | [μ] | [A/m] | density [T] | ratio [%] |
| 340 | 85 | 2,500 | 1,860 | 19.2 | 1.47 | 7.54 |
| 360 | 85 | 2,500 | 2,150 | 13.4 | 1.61 | 3.54 |
| 380 | 85 | 2,500 | 2,000 | 5.2 | 1.60 | 1.46 |
| 400 | 85 | 2,500 | 1,950 | 9.1 | 1.66 | 1.89 |
| 420 | 85 | 2,500 | 1,610 | 23.5 | 1.60 | 4.18 |

TABLE 2
Magnetic characteristics of a magnetic core according to a heat
treatment time (a measurement condition: 60 Hz, Hₘ ≈ 1,000 A/m)

| | | Magnetic | | | Saturation | |
|---|---|---|---|---|---|---|
| Temperature | Time | field | Permeability | Coercivity | magnetic flux | Squareness |
| [° C.] | [min] | [Gauss] | [μ] | [A/m] | density [T] | ratio [%] |
| 380 | 67 | 2,500 | 1,960 | 9.9 | 1.67 | 2.21 |
| 380 | 85 | 2,500 | 2,000 | 5.2 | 1.60 | 1.46 |
| 380 | 160 | 2,500 | 2,250 | 9.8 | 1.64 | 2.12 |
| 380 | 270 | 2,500 | 1,710 | 22.1 | 1.59 | 5.48 |

As illustrated in Table 1, main magnetic characteristics such as the permeability or coercivity of the magnetic core are changed according to the heat treatment temperature. The heat treatment temperature of 380° C. has been judged as the most preferable ideal temperature condition.

In addition, the Table 2 shows magnetic characteristics of a magnetic core according to a heat treatment time. The heat treatment time of about 85 minutes has been judged as the optimum magnetic characteristic.

Here, the heat treatment temperature profile is illustrated in FIG. 1, and an outer magnetic field is applied toward a width direction of an amorphous ribbon in order to improve the magnetic characteristics of the magnetic core.

Intensity of the magnetic field that is externally applied from the outside is 500 Gauss or more, preferably 2,000 Gauss or more. If a magnetic field is applied during performing a heat treatment process of the magnetic core, the magnetic characteristics such as the permeability, coercivity and squareness ratio of the magnetic core can be optimized. Intensity of the applied magnetic field relies upon the heat treatment environment such as the heat treatment methods and conditions. Accordingly, the intensity of the applied magnetic field cannot be specified as particular value. According to the inventors' research study, it is preferable that intensity of the applied magnetic field is 100 Gauss to 6,000 Gauss.

From the above-described results, when the heat treatment temperature is 380° C., the heat treatment time is 85 minutes, and the outer applied magnetic field intensity is 2,500 Gauss, it has been judged that the magnetic characteristics of the magnetic core are optimal.

According to the inventors' experimental result, it is preferable that the optimal heat treatment condition embodying the magnetic core for electric current sensors according to this invention, follow the heat treatment temperature of 200 to 600° C., the heat treatment time of 20 minutes to 1,000 minutes and the intensity of the applied magnetic field of 100 Gauss to 6,000 Gauss.

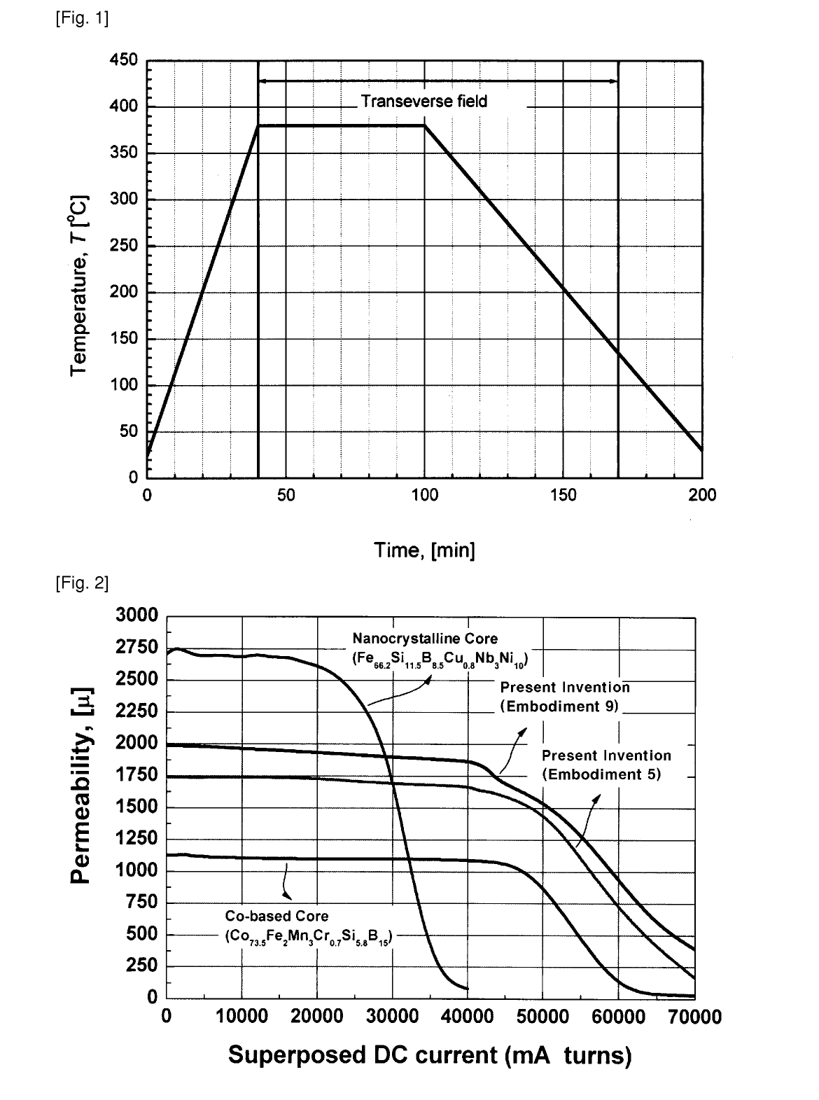

In order to confirm characteristics with respect to the DC electric current components on the basis of the above-described results, a direct-current superposition characteristic has been measured, and the measurement results are illustrated in FIG. 2, together with the conventional magnetic core.

Here, in the case that the primary electric current intensity is 120 A, the magnetic core should not be saturated until the DC electric current intensity becomes 42.4 A. Here, if a change of the permeability in the DC applied electric current occurs by 15% or higher, it is judged that the magnetic core has been saturated.

The direct-current superposition characteristic graph is a graph from which an electric current sensor is not saturated in the DC components (harmonics) and magnitude of available electric current can be seen. As illustrated in FIG. 2, the conventional nanocrystalline core using the Fe-based nanocrystalline alloys has an excessively high permeability. Accordingly, it can be confirmed that DC electric current components do not reach 42.4 A in view of an identical core volume.

On the other hand, it can be seen that the magnetic core according to this invention has a permeability higher than that of the Co-based amorphous core, and further magnitude of the DC electric current is in an equal level.

Therefore, since the magnetic core according to this invention can be embodied to have an optimal range of a permeability and a high saturation magnetic flux density, there are advantages that the magnetic core can be fabricated in a small size, and moreover a phase difference can be reduced.

Meanwhile, the following Table 3 illustrates results which have been obtained by comparing permeabilities and saturation magnetic flux densities of the conventional Fe-based nanocrystalline magnetic core (Comparative examples 1 and 2) and the Fe-based amorphous magnetic core (Embodiments 1 to 9) according to the present invention.

TABLE 3
Magnetic characteristics between the magnetic core according to the
present invention and the conventional magnetic core (a measurement
condition: 60 Hz, Hₘ≈ 1,000 A/m)

| | | | Permeability | Saturation magnetic |
|---|---|---|---|---|
| | | Alloy composition | [μ] | flux density [T] |
| Comparative | 1 | Fe_{66.2}Si_{11.5}B_{8.5}Cu_{0.8}Nb₃Ni₁₀ | 3,300~4,500 | 1.23 |
| examples | 2 | Fe_{65.2}Si_{11.5}B_{8.5}Cu_{0.8}Nb₃Ni₁₁ | 3,000~4,000 | 1.22 |
| Embodiments | 1 | Fe₇₄Si_{6.5}B₁₅Cr_{1.5}Ni₃ | 3,000~4,000 | 1.50 |
| | 2 | Fe₅₇Si_{6.5}B₁₅Cr_{1.5}Ni₂₀ | 2,200~3,000 | 1.25 |
| | 3 | Fe_{63.9}Si_{7.1}B_{14.5}Cr_{1.6}Ni_{12.8} | 3,700~4,700 | 1.26 |
| | 4 | Fe_{60.9}Si_{6.8}B_{14.2}Cr_{1.7}Ni_{16.5} | 3,400~4,500 | 1.30 |
| | 5 | Fe_{58.5}Si_{6.5}B_{13.5}Cr_{1.5}Ni₂₀ | 1,700~2,200 | 1.45 |
| | 6 | Fe_{56.2}Si_{6.3}B_{12.9}Cr_{1.4}Ni_{23.1} | 1,500~1,700 | 1.45 |
| | 7 | Fe_{54.1}Si_{6.1}B_{12.4}Cr_{1.3}Ni_{26.1} | 1,400~1,600 | 1.45 |
| | 8 | Fe_{58.5}Si_{6.5}B_{13.5}Cr_{1.5}Ni₁₀Co₁₀ | 2,600~3,800 | 1.44 |
| | 9 | Fe_{60.6}Si₅B_{14.4}CO₂₀ | 1,700~2,200 | 1.70 |

As can be seen from Table 3, it can be seen that the magnetic core according to this invention has advantages that the saturation magnetic flux density is very high as 1.7 T at maximum, and the permeability is kept within a range of 1,400 to 4,000. Accordingly, even in the case that the electric current includes DC electric current components, a use area for the DC components can be greatly secured.

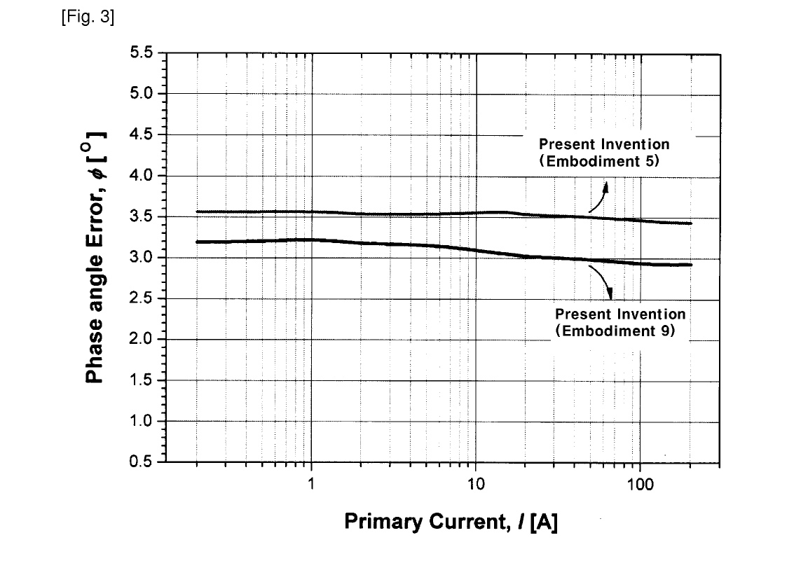

In addition, FIG. 3 is a graphical view illustrating a phase difference which has been measured using an electric current sensor employing a magnetic core according to an embodiment of the present invention. According to the measurement conditions, the magnetic core is obtained by winding the secondary winding coil by 2,500 turns with a line diameter of 0.22 mm. As illustrated in FIG. 3, in the result of fabricating an electric current sensor employing the magnetic core according to this invention and then measuring a phase difference between the primary and secondary electric currents, it can be confirmed that a change rate of the phase difference is within 0.4° by electric current bands. Therefore, there are advantages that the magnetic core according to the present invention has an excellent linearity of the phase difference by the electric current bands, as an important factor of the electric current sensor when the electric current sensor employs the magnetic core, to thus reduce burdens of an electronic circuit of a watt-hour meter or a software process in order to compensate for the change of the phase difference.

### MODE FOR INVENTION

As described above, the present invention has been described with respect to particularly preferred embodiments. However, the present invention is not limited to the above embodiments, and it is possible for one who has an ordinary skill in the art to make various modifications and variations, without departing off the spirit of the present invention. Thus, the protective scope of the present invention is not defined within the detailed description thereof but is defined by the claims to be described later and the technical spirit of the present invention.

### INDUSTRIAL APPLICABILITY

The present invention can be applicable for a magnetic core having an appropriate range of permeability and a high magnetic flux density, thereby being configured to have a small phase difference and a small size. The magnetic core can be use for electric current sensors.

1. A magnetic core for electric current sensors, the magnetic core made of an amorphous alloy having a composition represented by the general formula: FeₐM_{b}Si_{c}B_{d}M′ₑ, wherein M is at least one element that is selected from Ni and Co, and M′ is Cr, and a to e are atomic % and numbers satisfying 30≦a≦80, 1≦b≦50, 0.1≦c≦20, 0.1≦d≦20, and 0≦e≦10, respectively, and wherein the amorphous alloy has a magnetic flux density of 1.2 T to 1.7 T, and a permeability of 1,000 to 4,000.

2. The magnetic core for electric current sensors according to claim 1, wherein the element M is Ni in the general formula.

3. The magnetic core for electric current sensors according to claim 2, wherein a to e are atomic % and numbers satisfying 50≦a≦80, 3≦b≦30, 6≦c≦10, 10≦d≦20, and 0≦e≦5, respectively.

4. The magnetic core for electric current sensors according to claim 1, wherein e=0 when the element M is Co in the general formula.

5. The magnetic core for electric current sensors according to claim 1, wherein in the case of a heat treatment condition embodying the magnetic core for electric current sensors, a heat treatment temperature is 200 to 600° C., and a heat treatment time is 20 to 1,000 minutes, and intensity of an applied magnetic field is 100 to 6,000 Gauss.

6. The magnetic core for electric current sensors according to claim 1, wherein a phase difference between primary and secondary electric currents of the magnetic core for electric current sensors has a value of 10° or below.

7. The magnetic core for electric current sensors according to claim 1, wherein the amorphous alloy has a permeability of a value of 1,400 to 3,000.
